(19) United States
(12) Patent Application Publication
(10) Pub. No.: US 2025/0342082 A1
(43) Pub. Date: Nov. 6, 2025

(54) MEMORY AND MEMORY SYSTEM INCLUDING ECC DECODER CIRCUIT

(71) Applicant: SK hynix Inc., Gyeonggi-do (KR)

(72) Inventors: Jeong Je PARK, Gyeonggi-do (KR); Sang Sic YOON, Gyeonggi-do (KR)

(21) Appl. No.: 18/911,262

(22) Filed: Oct. 10, 2024

(30) Foreign Application Priority Data
May 2, 2024 (KR) 10-2024-0058552
Jul. 18, 2024 (KR) 10-2024-0094726

(51) Int. Cl. G06F 11/10

(52) U.S. Cl. CPC G06F 11/1068; G06F 11/106

(57) ABSTRACT

A memory may include a plurality of data terminals, a plurality of data receiving circuits configured to receive data and a parity through the plurality of data terminals, an error correction code (ECC) decoder circuit configured to detect errors in the data and the parity using the data and the parity, and an error storage circuit configured to store a history of the errors detected by the ECC decoder circuit.

### CROSS-REFERENCE TO RELATED APPLICATION(S)

This application claims priority under 35 U.S.C. § 119 to Korean Patent Application No. 10-2024-0058552, filed on May 2, 2024, and Korean Patent Application No. 10-2024-0094726, filed on Jul. 18, 2024, the disclosures of which are incorporated herein by reference in their entirety.

### BACKGROUND

### 1. Technical Field

Various embodiments of the present disclosure relate to a memory and a memory system.

### 2. Related Art

In the early stage of the semiconductor memory industry, a number of originally good dies with no defective memory cells in a memory chip fabricated through a semiconductor fabrication process were distributed on a wafer. However, as the capacity of a memory gradually increases, it becomes difficult to fabricate a memory that does not have any defective memory cells, and nowadays, it may be said that there are substantially no chances that such a memory can be fabricated. One way to resolve this concern is to repair defective memory cells in a memory with redundant memory cells.

Another way is to use an error correction code circuit, i.e., an ECC engine, in a memory system, to correct errors that occur in memory cells and errors that occur when data is transmitted during read and write processes of the memory system.

### SUMMARY

In accordance with an embodiment of the present disclosure, a memory may include a plurality of data terminals; a plurality of data receiving circuits configured to receive data and a parity through the plurality of data terminals; an error correction code (ECC) decoder circuit configured to detect errors in the data and the parity using the data and the parity; and an error storage circuit configured to store a history of the errors detected by the ECC decoder circuit.

In accordance with an embodiment of the present disclosure, a memory system may include a plurality of data lines; a first data clock line and a second data clock line; a memory controller configured to transmit data and a parity through the plurality of data lines and transmit a data clock through the first and second data clock lines; and a memory configured to receive the data clock through the first and second data clock lines and receive the data and the parity transmitted through the plurality of data lines, in synchronization with the data clock, wherein the memory may include an ECC decoder circuit configured to detect errors in the data and the parity based on the data and the parity; and an error storage circuit configured to store a history of the errors detected by the ECC decoder circuit for each data line.

In accordance with an embodiment of the present disclosure, an operating method of a memory system may include generating, by a memory controller, a parity based on data; transmitting, by the memory controller, a data clock through a first data clock line and a second data clock line; transmitting, by the memory controller, the data and the parity through a plurality of data lines; receiving, by a memory, the data clock through the first and second data clock lines; receiving, by the memory, the data and the parity through the plurality of data lines in synchronization with the data clock; detecting, by the memory, errors in the data and the parity based on the data and the parity; and storing, by the memory, a history of error occurrences for each data line.

In accordance with an embodiment of the present disclosure, a memory system may include a plurality of data lines; data clock lines; a memory controller configured to transmit data and a parity to the plurality of data lines and transmit a data clock to the data clock lines; and a memory configured to, in synchronization with the data clock transmitted through the one or more data clock lines, receive the data and the parity through the plurality of data lines and store a history of errors detected by decoding the received data and parity for each data line.

### BRIEF DESCRIPTION OF THE DRAWINGS

FIG. 1 is a block diagram illustrating a memory system in accordance with an embodiment of the present disclosure.

FIG. 2 is a block diagram illustrating the memory illustrated in FIG. 1, in accordance with an embodiment of the present disclosure.

FIG. 3 is a block diagram illustrating the data receiving circuit illustrated in FIG. 2, in accordance with an embodiment of the present disclosure.

FIG. 4 is a block diagram illustrating the data output circuit illustrated in FIG. 2, in accordance with an embodiment of the present disclosure.

FIG. 5 is a block diagram illustrating the memory controller illustrated in FIG. 1, in accordance with an embodiment of the present disclosure.

FIG. 6 is a flowchart illustrating a process of a training operation for adjusting timing of data and a data clock of the memory system illustrated in FIGS. 1 to 5, in accordance with an embodiment of the present disclosure.

### DETAILED DESCRIPTION

Various embodiments of the present disclosure are directed to technology of performing a training operation by using an error correction function of a memory.

According to embodiments of the present disclosure, it is possible to perform a training operation by using an error correction function of a memory.

Hereinafter, various embodiments according to the technical spirit of the present disclosure are described below with reference to the accompanying drawings.

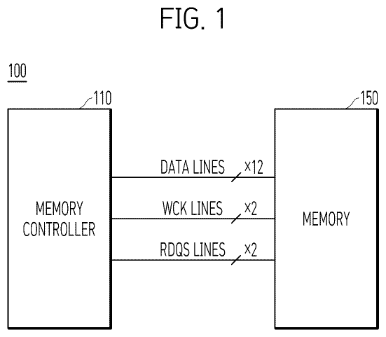

FIG. 1 is a block diagram illustrating a memory system 100 in accordance with an embodiment of the present disclosure. Diagrams of FIGS. 1 to 6 illustrate only the parts directly related to transmission of data and a data clock in the memory system 100.

Referring to FIG. 1, the memory system 100 may include a memory controller 110 and a memory 150.

The memory controller 110 may control read and write operations of the memory 150 according to a request of a host, and the memory 150 may perform the read and write operations under the control of the memory controller 110.

Data lines DATA LINES may be lines for transmitting data between the memory controller 110 and the memory 150. During the write operation, data may be transmitted from the memory controller 110 to the memory 150, and during the read operation, data may be transmitted from the memory 150 to the memory controller 110. In FIG. 1, it is described as an example that the number of the data lines DATA LINES is 12. In order to correct errors in the data transmitted between the memory controller 110 and the memory 150, a parity may be transmitted along with the data on the data lines DATA LINES.

Data clock lines WCK LINES may be lines for transmitting a data clock from the memory controller 110 to the memory 150. In FIG. 1, it is described as an example that the data clock lines WCK LINES are two lines because the data clock is a differential signal. The data clock may be a clock used by the memory 150 to receive data transmitted through the data lines DATA LINES during the write operation.

Read data strobe signal lines RDQS LINES may be lines for transmitting a read data strobe signal from the memory 150 to the memory controller 110. In FIG. 1, it is described as an example that the read data strobe signal lines RDQS LINES are two lines because the read data strobe signal is a differential signal. The read data strobe signal may be a signal used by the memory controller 110 to receive data transmitted through the data lines DATA LINES during the read operation.

Timing adjustment between the data transmitted through the data lines DATA LINES and the data clock transmitted through the data clock lines WCK LINES is essential in order for the memory 150 to correctly receive the data transmitted through the data lines DATA LINES, and a training operation for the timing adjustment is referred to as “WCK-DQ training”.

The WCK-DQ training is generally performed during a period in which data is not inputted/outputted to/from the memory 150, such as an all bank refresh state (i.e., all bank refresh operation period). The WCK-DQ training is performed through the following process. First, a predetermined data pattern is stored in the memory 150. The data clock and data having the predetermined data pattern are transmitted from the memory controller 110 to the memory 150, and the memory 150 receives the data based on the data clock. The memory 150 compares the received data with the predetermined data pattern and counts the number of errors for each data line DATA LINES. The error counting result of the memory 150 is transmitted to the memory controller 110, and the memory controller 110 adjusts timing of the data and the data clock based on the result.

The process of the WCK-DQ training may be complicated because the WCK-DQ training requires storing the predetermined data pattern in the memory 150 using, for example, a mode register write (MRW) operation and detecting errors by comparing the data received by the memory 150 with the stored data pattern during the training operation. Hereinafter, a method of performing the training operation using an error correction code (ECC) decoder circuit included in the memory 150 is described.

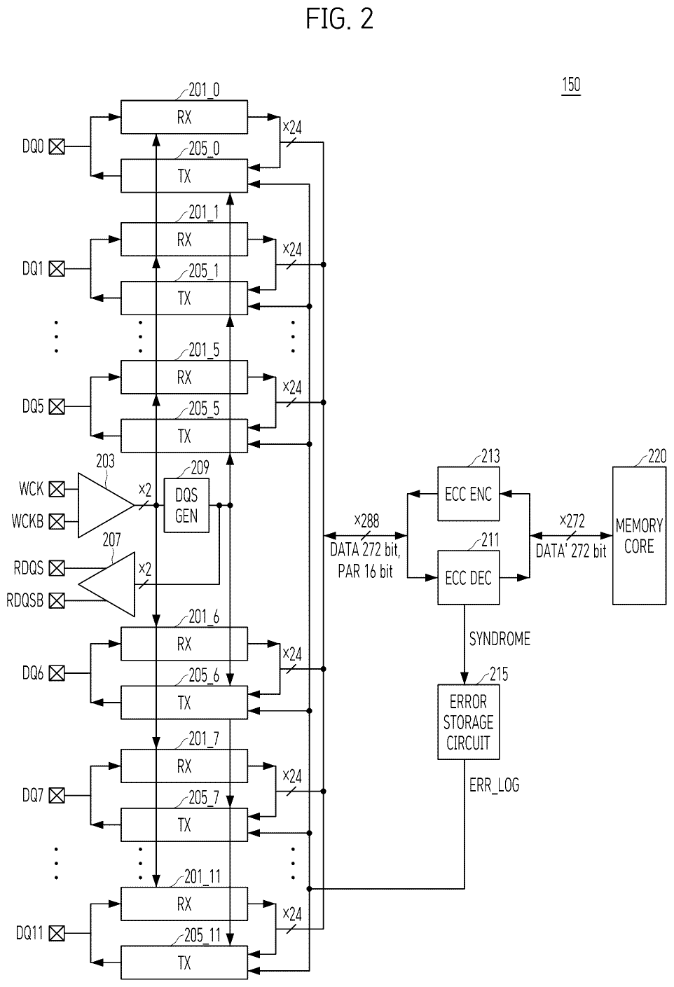

FIG. 2 is a block diagram illustrating the memory 150 illustrated in FIG. 1, in accordance with an embodiment of the present disclosure.

Referring to FIG. 2, the memory 150 may include data terminals DQ0 to DQ11, data clock terminals WCK and WCKB, read data strobe signal terminals RDQS and RDQSB, data receiving circuits (RXs) 201_0 to 201_11, a data clock receiver 203, a strobe generation circuit (DQS GEN) 209, data transmitting circuits (TXs) 205_0 to 205_11, a read data strobe signal transmitter 207, an ECC decoder circuit (ECC DEC) 211, an ECC encoder circuit (ECC ENC) 213, an error storage circuit 215, and a memory core 220.

The data clock terminals WCK and WCKB are connected to the data clock lines (indicated by reference symbol “WCK LINES” in FIG. 1). The data clock receiver 203 may receive the data clock transmitted through the data clock terminals WCK and WCKB and transmit the received data clock to the data receiving circuits 201_0 to 201_11 and the strobe generation circuit 209. Because the data clock is a differential signal, reference symbol “x2” is indicated in the drawing.

The data terminals DQ0 to DQ11 are connected to the data lines DATA LINES. During the write and read operations, data may be transmitted and received at burst length (BL) of 24 to and from each of the data terminals DQ0 to DQ11. That is, during the write operation, 24 bits of data (and parity) may be inputted in series to each of the data terminals DQ0 to DQ11, and during the read operation, 24 bits of data (and parity) may be outputted in series to each of the data terminals DQ0 to DQ11.

The data receiving circuits 201_0 to 201_11 may receive data DATA and a parity PAR transmitted through the data terminals DQ0 to DQ11. The data receiving circuits 201_0 to 201_11 may operate in synchronization with a data clock received by the data clock receiver 203. The data receiving circuits 201_0 to 201_11 may receive the data DATA and parity PAR of the data terminals DQ0 to DQ11, convert the received data DATA and parity PAR in a serial-to-parallel manner and output the converted data and parity. The data receiving circuits 201_0 to 201_11 may receive 288 (=12*24) bits of signal inputted to 12 of the data terminals DQ0 to DQ11, of which 272 bits may be the data DATA, and 16 bits may be the parity PAR.

The strobe generation circuit 209 may generate the read data strobe signal based on the data clock transmitted from the data clock receiver 203. Because the read data strobe signal is a differential signal, reference symbol “x2” is indicated in the drawing. The read data strobe signal may be transmitted to the data transmitting circuits 205_0 to 205_11 and the read data strobe signal transmitter 207. The read data strobe signal transmitter 207 may transmit the read data strobe signal to the read data strobe signal terminals RDQS and RDQSB. The read data strobe signal terminals RDQS and RDQSB are terminals to which the read data strobe signal lines (indicated by reference symbol “RDQS LINES” in FIG. 1) are connected.

The data transmitting circuits 205_0 to 205_11 may transmit the data DATA and parity PAR transmitted from the ECC encoder circuit 213 to the data terminals DQ0 to DQ11. The data transmitting circuits 205_0 to 205_11 may operate in synchronization with the read data strobe signal. The data transmitting circuits 205_0 to 205_11 may convert the data DATA and the parity PAR in a parallel-to-serial manner, and then output the converted data and parity to the data terminals DQ0 to DQ11.

The ECC decoder circuit 211 may detect and correct errors in the data DATA and parity PAR using the data DATA and parity PAR transmitted from the data receiving circuits 201_0 to 201_11. That is, the ECC decoder circuit 211 may detect the errors in the data DATA and parity PAR transmitted from the memory controller 110 and correct the detected errors. The ECC decoder circuit 211 may generate a syndrome SYNDROME using the data DATA and the parity PAR. The syndrome SYNDROME is information indicating which bit of the bits of the data DATA and the bits of the parity PAR has errors. The ECC decoder circuit 211 may correct the errors by inverting the bit corresponding to the syndrome SYNDROME. The syndrome SYNDROME generated by the ECC decoder circuit 211 may be transmitted to the error storage circuit 215.

The error storage circuit 215 may store a history of the errors detected by the ECC decoder circuit 211. The error storage circuit 215 may receive the syndrome SYNDROME from the ECC decoder circuit 211 and store a history of error occurrence for each data terminal DQ0 to DQ11 using the syndrome SYNDROME. Specifically, the error storage circuit 215 may count and store the number of errors occurring for each data terminal DQ0 to DQ11. Because the syndrome SYNDROME includes information about which bit of 288 bits of the data DATA and parity PAR contains errors, the error storage circuit 215 may recognize, using the syndrome SYNDROME, that errors are present in data or the syndrome corresponding to a data terminal among the data terminals DQ0 to DQ11, and accumulate and store the history of the errors. Error history information ERR_LOG stored in the error storage circuit 215 may be transmitted to the memory controller 110 according to a request of the memory controller 110. The error history information ERR_LOG may be transmitted to the memory controller 110 through the data transmitting circuits 205_0 to 205_11.

The memory core 220 may receive and store data DATA′ processed by the ECC decoder circuit 211 during the write operation. In addition, the memory core 220 may transmit the stored data DATA′ to the ECC encoder circuit 213 during the read operation. The memory core 220 represents a place where data is stored in the memory 150, and may include a plurality of memory cells that store data and circuits that write and read data to and from the plurality of memory cells.

The ECC encoder circuit 213 may generate the parity PAR using the data DATA′ read from the memory core 220 during the read operation. That is, the ECC encoder circuit 213 may encode the data DATA′ and generate the parity PAR used to correct errors in the data DATA′ in the memory controller 110. Because during an encoding operation, the parity PAR is just generated, and an error correction operation is not performed, the data DATA′ inputted to the ECC encoder circuit 213 and the data DATA outputted from the ECC encoder circuit 213 during the encoding operation may be the same.

The number of data terminals DQ, a value of BL, the number of bits of parity PAR, etc. in FIGS. 1 and 2 are merely examples and may be changed at any time depending on design.

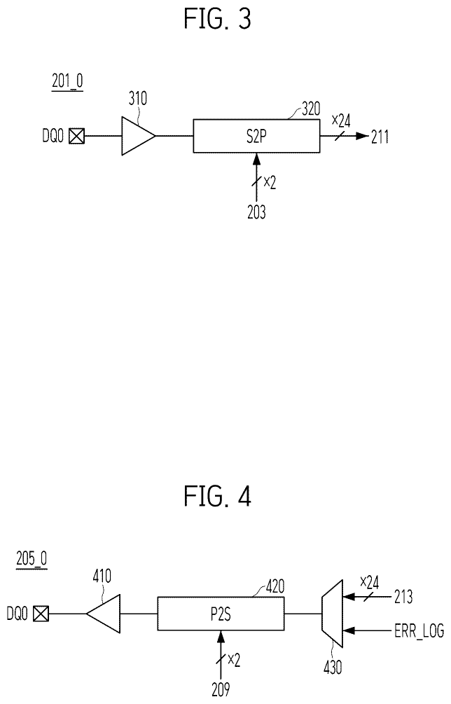

FIG. 3 is a block diagram illustrating the data receiving circuit 201_0 illustrated in FIG. 2, in accordance with an embodiment of the present disclosure.

Referring to FIG. 3, the data receiving circuit 201_0 may include a data receiver 310 and a serial-to-parallel conversion circuit (S2P) 320.

The data receiver 310 may receive a signal from the data terminal DQ0. The serial-to-parallel conversion circuit 320 may convert a reception result of the data receiver 310 in a serial-to-parallel manner. Because a 24-bit signal is transmitted in series at burst length (BL) of 24 through the data terminal DQ0 at BL=24, the serial-to-parallel conversion circuit 320 may perform a serial-to-parallel conversion operation at 1:24. The serial-to-parallel conversion circuit 320 may use the data clock transmitted from the data clock receiver 203 for data alignment and the serial-to-parallel conversion operation.

The other data receiving circuits 201_1 to 201_11 besides the data receiving circuit 201_0 may also be configured in the same manner as the data receiving circuit 201_0 illustrated in FIG. 3.

FIG. 4 is a block diagram illustrating the data transmitting circuit 205_0 illustrated in FIG. 2, in accordance with an embodiment of the present disclosure.

Referring to FIG. 4, the data transmitting circuit 205_0 may include a data transmitter 410, a parallel-to-serial conversion circuit (P2S) 420, and a selection circuit 430.

The selection circuit 430 may select one of a signal transmitted from the ECC encoder circuit 213 and the error history information ERR_LOG. The selection circuit 430 may select the signal transmitted from the ECC encoder circuit 213 during the read operation and select the error history information ERR_LOG when the memory 150 transmits the error history information ERR_LOG to the memory controller 110 at the request of the memory controller 110.

The parallel-to-serial conversion circuit 420 may convert a signal selected by the selection circuit 430 in the parallel-to-serial manner. The parallel-to-serial conversion circuit 420 may perform a parallel-to-serial conversion operation at 24:1 and use the read data strobe signal generated by the strobe generation circuit 209 for the parallel-to-serial conversion operation.

The data transmitter 410 may transmit a conversion result of the parallel-to-serial conversion circuit 420 to the data terminal DQ0.

Although FIG. 2 illustrates that the error history information ERR_LOG is outputted through the data transmitting circuits 205_0 to 205_11, the error history may be outputted through some of the data transmitting circuits 205_0 to 205_11 when the number of bits of the error history information ERR_LOG is small. In this case, the selection circuit 430 may be omitted in data transmitting circuits that do not output the error history information ERR_LOG among the data transmitting circuits 205_0 to 205_11.

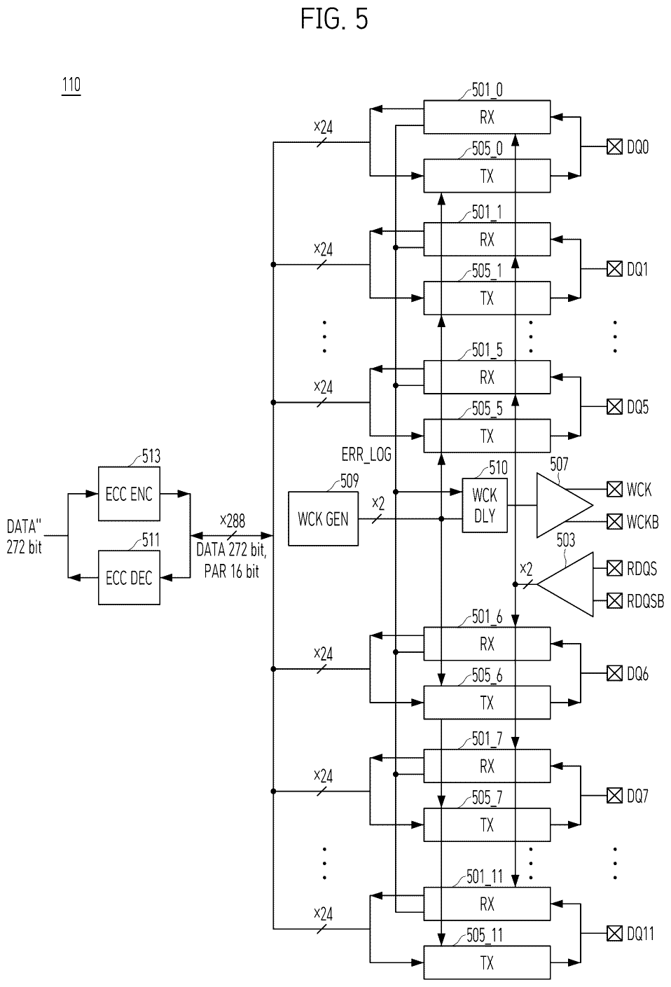

FIG. 5 is a block diagram illustrating the memory controller 110 illustrated in FIG. 1, in accordance with an embodiment of the present disclosure.

Referring to FIG. 5, the memory controller 110 may include data terminals DQ0 to DQ11, data clock terminals WCK and WCKB, read data strobe signal terminals RDQS and RDQSB, data receiving circuits (RXs) 501_0 to 501_11, a read data strobe signal receiver 503, a data clock generation circuit (WCK GEN) 509, a data clock timing adjustment circuit (WCK DLY) 510, data transmitting circuits (TXs) 505_0 to 505_11, a data clock transmitter 507, an ECC decoder circuit (ECC DEC) 511, and an ECC encoder circuit (ECC ENC) 513.

The read data strobe signal terminals RDQS and RDQSB are connected to the read data strobe signal lines (indicated by reference symbol “RDQS LINES” in FIG. 1). The read data strobe signal receiver 503 may receive the read data strobe signal transmitted to the read data strobe signal terminals RDQS and RDQSB and transmit the received read data strobe signal to the data receiving circuits 501_0 to 501_11. Because the read data strobe signal is a differential signal, reference symbol “x2” is indicated in the drawing.

The data terminals DQ0 to DQ11 are connected to the data lines DATA LINES. During the write and read operations, data may be transmitted and received at burst length (BL) of 24 to each of the data terminals DQ0 to DQ11. That is, during the read operation, 24 bits of data (and parity) may be inputted in series to each of the data terminals DQ0 to DQ11, and during the write operation, 24 bits of data (and parity) may be outputted in series to each of the data terminals DQ0 to DQ11.

The data receiving circuits 501_0 to 501_11 may receive data DATA and a parity PAR transmitted through the data terminals DQ0 to DQ11. The data receiving circuits 501_0 to 501_11 may operate in synchronization with the read data strobe signal received by the read data strobe signal receiver 503. The data receiving circuits 501_0 to 501_11 may receive the data DATA and parity PAR of the data terminals DQ0 to DQ11, convert the received data DATA and parity PAR in a serial-to-parallel manner and output the converted data and parity. The data receiving circuits 501_0 to 501_11 may receive 288 (=12*24) bits of signal inputted to 12 of the data terminals DQ0 to DQ11, of which 272 bits may be the data DATA, and 16 bits may be the parity PAR.

The data clock generation circuit 509 may generate the data clock used to transmit data from the memory controller 110 to the memory 150. Because the data clock is a differential signal, reference symbol “x2” is indicated in the drawing. The data clock generated by the data clock generation circuit 509 may be transmitted to the data transmitting circuits 505_0 to 505_11 and the data clock timing adjustment circuit 510.

The data clock timing adjustment circuit 510 may adjust timing of the data clock transmitted from the memory controller 110 to the memory 150. The data clock timing adjustment circuit 510 may delay the data clock and transmit the delayed data clock to the data clock transmitter 507, and a delay value of the data clock timing adjustment circuit 510 may be adjusted by the error history information ERR_LOG transmitted from the memory 150. The data clock transmitter 507 may transmit the data clock whose timing is adjusted by the data clock timing adjustment circuit 510 to the data clock terminals WCK and WCKB. The data clock terminals WCK and WCKB are terminals to which the data clock lines (indicated by reference symbol “WCK LINES” in FIG. 1) are connected.

The data transmitting circuits 505_0 to 505_11 may transmit the data DATA and parity PAR transmitted from the ECC encoder circuit 513 to the data terminals DQ0 to DQ11. The data transmitting circuits 505_0 to 505_11 may operate in synchronization with the data clock generated by the data clock generation circuit 509. The data transmitting circuits 505_0 to 505_11 may convert the data DATA and the parity PAR in a parallel-to-serial manner, and then output the converted data and parity to the data terminals DQ0 to DQ11.

The ECC decoder circuit 511 may detect and correct errors in the data DATA and parity PAR using the data DATA and parity PAR transmitted from the data receiving circuits 501_0 to 501_11. That is, the ECC decoder circuit 511 may detect the errors in the data DATA and parity PAR transmitted from the memory 150 and correct the detected errors. Data DATA″ is data processed by the ECC decoder circuit 511.

The ECC encoder circuit 513 may generate the parity PAR using the data DATA″, that is, write data, to be transmitted from the memory controller 150 to the memory 110. Because during an encoding operation, the parity PAR is just generated, and an error correction operation is not performed, the data DATA″ inputted to the ECC encoder circuit 513 and the data DATA outputted from the ECC encoder circuit 513 during the encoding operation may be the same.

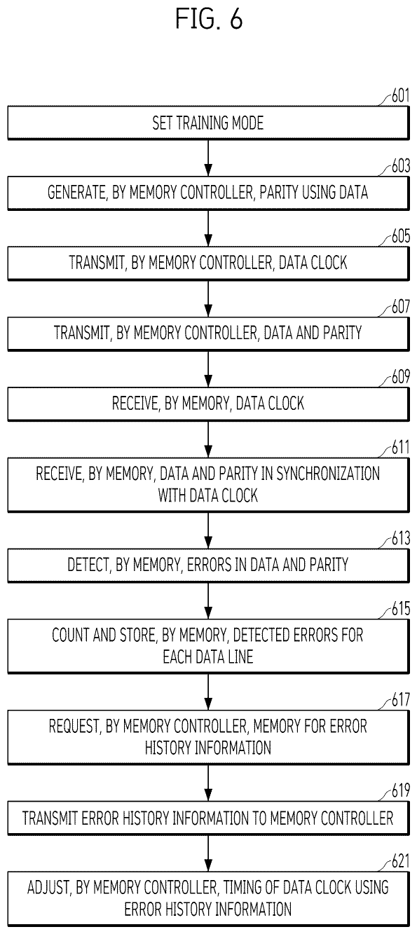

FIG. 6 is a flowchart illustrating a process of the training operation for adjusting timing of the data and the data clock of the memory system 100 illustrated in FIGS. 1 to 5, in accordance with an embodiment of the present disclosure.

Referring to FIG. 6, a training mode for adjusting the timing of the data and the data clock may be set in operation 601. The training operation for controlling the timing of the data and the data clock is referred to as a “WCK-DQ training operation”. The training operation is generally performed during a period in which data is not transmitted between the memory 150 and the memory controller 110, such as an all bank refresh state (i.e., all bank refresh operation period).

The ECC encoder circuit 513 of the memory controller 110 may generate the parity PAR using the data DATA″ in operation 603.

The data clock transmitter 507 of the memory controller 110 may transmit the data clock to the data clock lines WCK LINES in operation 605, and the data transmitting circuits 505_0 to 505_11 may transmit the data DATA and the parity PAR to the data lines DATA LINES in operation 607.

The data clock receiver 203 of the memory 150 may receive the data clock from the data clock lines WCK LINES in operation 609, and the data receiving circuits 201_0 to 201_11 in synchronization with the data clock received by the data clock receiver 203 may receive the data DATA and the parity PAR from the data lines DATA LINES in operation 611.

The ECC decoder circuit 211 of the memory 150 may detect errors in the data DATA and the parity PAR using the data DATA and the parity PAR received by the data receiving circuits 201_0 to 201_11 in operation 613.

The error storage circuit 215 of the memory 150 may count and store the errors detected by the ECC decoder circuit 211 for each data line DATA LINES, that is, each data terminal DQ0 to DQ11, in operation 615.

The memory controller 110 may request the memory 150 for the history of error occurrence in operation 617. This request may be performed by the memory controller 110 applying a mode register read (MRR) command to the memory 150. In response to the request, the memory 150 may transmit the error history information ERR_LOG stored in the error storage circuit 215 to the memory controller 110 in operation 619.

The data clock timing adjustment circuit 510 of the memory controller 110 may adjust the timing of the data clock using the error history information ERR_LOG transmitted from the memory 150, in operation 621.

The processes of 603, 605, 607, 609, 611, 613, 615, 617, 619, and 621 of FIG. 6 may be performed multiple times. For example, the training operation may be performed such that the processes of 603, 605, 607, 609, 611, 613, and 615 are repeatedly performed 10 times, the processes of 617, 619, and 621 are performed once, the processes of 603, 605, 607, 609, 611, 613, and 615 are repeatedly performed 10 times again, and then the processes of 617, 619, and 621 are performed once.

Although embodiments according to the technical spirit of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical spirit of the present disclosure defined in the following claims, and it should be construed that these substitutions, modifications, and changes belong to the scope of the present disclosure. Furthermore, the embodiments may be combined to form additional embodiments.

What is claimed is:

1. A memory comprising:
a plurality of data terminals;
a plurality of data receiving circuits configured to receive data and a parity through the plurality of data terminals;
an error correction code (ECC) decoder circuit configured to detect errors in the data and the parity based on the data and the parity; and
an error storage circuit configured to store a history of the errors detected by the ECC decoder circuit.

2. The memory of claim 1, wherein the error storage circuit is configured to store the history of error occurrence for each data terminal.

3. The memory of claim 2, wherein the error storage circuit is configured to count and store a number of error occurrence for each data terminal.

4. The memory of claim 2, wherein the plurality of data receiving circuits are configured to operate in synchronization with a data clock.

5. The memory of claim 4, further comprising:
a first data clock terminal;
a second data clock terminal; and
a data clock receiver configured to receive the data clock through the first and second data clock terminals and transmit the data clock to the plurality of data receiving circuits.

6. The memory of claim 4, wherein each of the plurality of data receiving circuits includes:
a data receiver; and
a serial-to-parallel conversion circuit configured to convert a reception result of the data receiver in a serial-to-parallel manner, in synchronization with the data clock.

7. The memory of claim 2, wherein the history of error occurrence stored in the error storage circuit is transmitted to a memory controller according to a request of the memory controller.

8. The memory of claim 5, further comprising:
a memory core configured to store data processed by the ECC decoder circuit;
an ECC encoder circuit configured to generate the parity based on the data read from the memory core; and
a plurality of data transmitting circuits configured to transmit, through the plurality of data terminals, the data read from the memory core and the parity generated by the ECC encoder circuit.

9. The memory of claim 8, wherein the plurality of data transmitting circuits are configured to operate in synchronization with a read data strobe signal.

10. The memory of claim 9, further comprising:
a strobe generation circuit configured to generate the read data strobe signal based on the data clock;
a first read data strobe signal terminal;
a second read data strobe signal terminal; and
a read data strobe signal transmitter configured to transmit the read data strobe signal through the first and second read data strobe signal terminals.

11. The memory of claim 7, wherein the error storage circuit is configured to receive a syndrome generated by the ECC decoder circuit.

12. A memory system comprising:
a plurality of data lines;
a first data clock line and a second data clock line;
a memory controller configured to transmit data and a parity through the plurality of data lines and transmit a data clock through the first and second data clock lines; and
a memory configured to receive the data clock through the first and second data clock lines and receive the data and the parity transmitted through the plurality of data lines, in synchronization with the data clock,
wherein the memory includes:
an ECC decoder circuit configured to detect errors in the data and the parity based on the data and the parity; and
an error storage circuit configured to store a history of the errors detected by the ECC decoder circuit for each data line.

13. The memory system of claim 12, wherein the error storage circuit is configured to count and store a number of error occurrences for each data line.

14. The memory system of claim 12, wherein the memory further includes a plurality of data receiving circuits configured to receive the data and the parity through the plurality of data lines, in synchronization with the data clock.

15. The memory system of claim 14, wherein each of the plurality of data receiving circuits includes:
a data receiver; and
a serial-to-parallel conversion circuit configured to convert a reception result of the data receiver in a serial-to-parallel manner, in synchronization with the data clock.

16. The memory system of claim 12,
wherein the history of the errors stored in the error storage circuit is transmitted from the memory to the memory controller, and
wherein the memory controller is configured to adjust timing of the data and data clock to be transmitted, based on the history of the errors transmitted from the memory.

17. An operating method of a memory system including a memory and a memory controller, the operating method comprising:
generating, by the memory controller, a parity based on data;
transmitting, by the memory controller, a data clock through a first data clock line and a second data clock line;
transmitting, by the memory controller, the data and the parity through a plurality of data lines;
receiving, by the memory, the data clock through the first and second data clock lines;
receiving, by the memory, the data and the parity through the plurality of data lines in synchronization with the data clock;
detecting, by the memory, errors in the data and the parity based on the data and the parity; and
storing, by the memory, a history of error occurrences for each data line.

18. The operating method of claim 17, further comprising:
transmitting, by the memory, the history of error occurrences to the memory controller; and
adjusting, by the memory controller, timing of the data clock and the data based on the history of error occurrences.

19. The operating method of claim 18, wherein transmitting the history of error occurrences and adjusting the timing of the data clock and the data are performed during a period in which no data transmission or reception is present between the memory and the memory controller.

20. The operating method of claim 19, wherein the period includes an all bank refresh operation period of the memory.

21. A memory system comprising:
a plurality of data lines;
one or more data clock lines;
a memory controller configured to transmit data and a parity to the plurality of data lines and transmit a data clock to the one or more data clock lines; and
a memory configured to, in synchronization with the data clock transmitted through the one or more data clock lines, receive the data and the parity through the plurality of data lines and store a history of errors detected by decoding the received data and parity for each data line.

22. The memory system of claim 21, wherein the memory is configured to transmit the history of errors to the memory controller according to a request of the memory controller.

23. The memory system of claim 22, wherein the memory controller is configured to adjust timing of the data clock and the data to be transmitted, based on the history of errors transmitted from the memory.
